(19) United States
(12) Patent Application Publication
(10) Pub. No.: US 2015/0008791 A1
(43) Pub. Date: Jan. 8, 2015

(54) NANOMETER ELECTRICAL GENERATOR

(71) Applicant: TriXcel, LLP, Newbury, MA (US)

(72) Inventor: Berj A. TERZIAN, NEWBURY, MA (US)

(73) Assignee: TriXcel, LLP, Newbury, MA (US)

(21) Appl. No.: 13/945,496

(22) Filed: Jul. 18, 2013

Related U.S. Application Data
(63) Continuation-in-part of application No. 13/936,075, filed on Jul. 5, 2013.

(51) Int. Cl. H02N 2/18; H01L 41/113

(52) U.S. Cl. CPC H02N 2/183; H02N 2/181; H01L 41/113
USPC 310/319; 310/339

(57) ABSTRACT

A piezoelectric generator is developed by providing a closed vessel within which piezoelectric powders of nanometer sizes are placed with an inert impact material and a viscous inert liquid which maintains the mixture in a cloud-like condition. A small empty space is preferably maintained in the vessel to enable free motion of the mixture when the vessel is moved. The impact material collides with the piezoelectric crystals to generate voltage pulses, and an electric current is created through one or more conductive wires in the vessel.

This is a continuation in part of U.S. patent application Ser. No. 13/936,075, filed Jul. 5, 2013.

### FIELD OF THE INVENTION

This invention relates to a novel electrical generator based on nanometer particles of piezoelectric crystals and other active elements included in coordination with each other.

### DESCRIPTION OF THE PRIOR ART

Prior efforts have attempted to develop a portable electrical generator that can be included in consumer devices such as cellphones, radios, iPhones, iPods and other products that need to be periodically recharged with electrical energy.

For example, Faraday components have been incorporated in the cited products in the hope that physical motion of the products can translate such motion into electrical energy, e.g., U.S. Pat. Nos. 7,719,145; 7,485,992; and 7,479,715. Other attempts have tried to incorporate piezoelectric crystals into the cited devices with internal mobile weights that could impact the crystals and thereby generate electrical pulses. These efforts have not been developed into practical utility.

### SUMMARY OF THE INVENTION

This invention comprises a closed vessel that contains piezoelectric powders and inert particles in a liquid that creates impacts of the particles on the piezoelectric powders, thus generating voltages that are harvested by at least one conductive wire to crease a current that will charge or recharge the above-cited devices.

### DESCRIPTION OF THE DRAWINGS

FIG. 1 is a closed vessel containing the components that comprise an electric generator.

FIG. 2 is a cross section of the vessel.

FIG. 3 is a schematic of a circuit that passes current through the vessel.

FIG. 4 illustrates a closed vessel with stationary piezoelectric material.

### DETAILED DESCRIPTION OF THE INVENTION

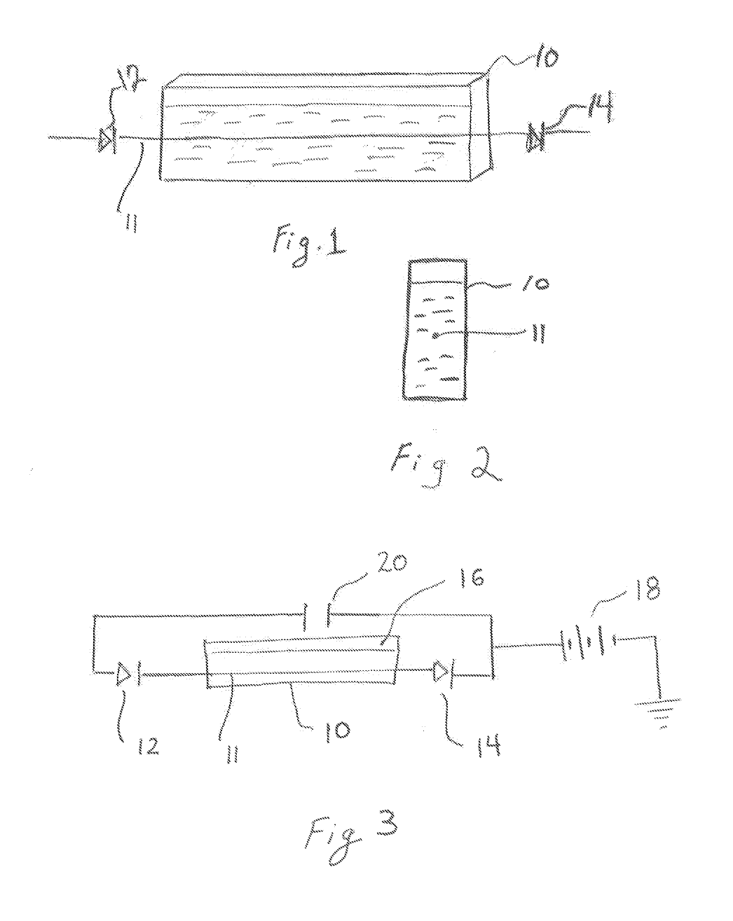

FIG. 1 comprises a rectangular closed vessel 10. Other vessels can be used, for example, a tube or any other closed shape. Within vessel 10 are several components, said particles of piezoelectric crystals, inert solid impact materials, and a liquid which is sufficiently viscous to keep the crystals and impact materials in mixed condition.

Also included in vessel 10 is at least one or more conductive wires 11 that pass through the vessel, as well as external diodes 12 and 14 outside the vessel. The section of the wire within the vessel is conductive and exposed to voltage and current generated in the vessel. The wires extending out of vessel 10 are preferably covered with insulation to maintain current through those sections.

The piezoelectric powder can be from 300 to 500 nanometer particle sizes. The impact material, for example, inert sand can be of a similar particle size. These sizes create a cloud-like mixture due to sufficient viscous liquid that will maintain intimate mixture or the solid piezoelectric crystals and the inert impact materials.

Motion of the vessel will cause random movement of the liquid thus creating continuous or near continuous electric impacts and pulses to create voltage and current. Diodes 12 and 14 will maintain direct current in a single direction through the wire within and outside the vessel. Since vessel 10 will be within a device that will be portable and carried during use, current will be generated virtually continuously.

FIG. 2 shows that the wire 11 within vessel 10 is in a central position and submerged within the liquid. A small empty space is preferably included to enable the liquid to freely slosh and move during use.

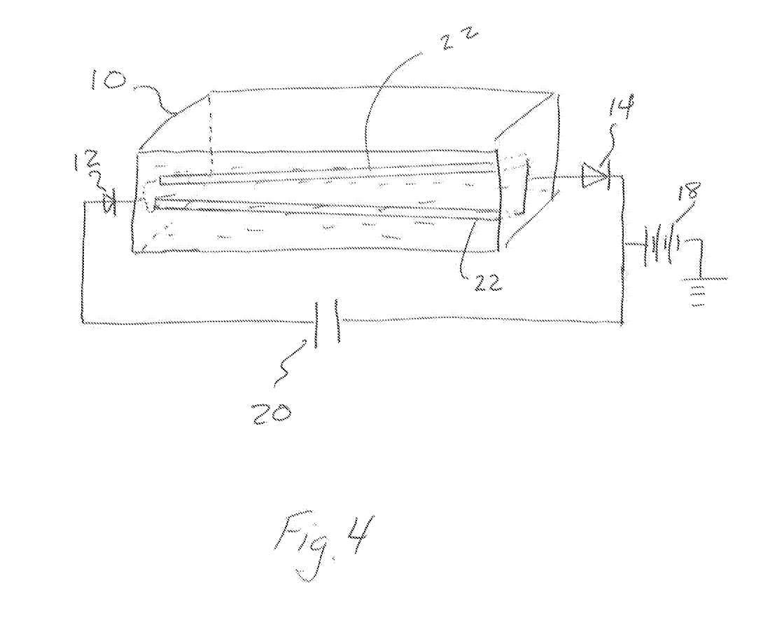

FIG. 3 displays schematic circuits connected to the piezoelectric generator. The small space 16 of the liquid level will promote motion of the liquid in the cloud-like mixture of piezoelectric powder and inert impact material. The current developed by diodes 12 and 14 flows to rechargeable battery 18 or capacitor 20 during use.

In a further embodiment, a conductive liquid is used in the initial embodiment, instead of the non-conductive liquid for example, sea water. The high conductivity will enhance the ability to harvest the voltage and currents generated by the collisions between the nanoparticles of piezoelectric crystal and the impact material.

In yet another embodiment shown in FIG. 4, the piezoelectric material 22 is positioned in a stationary condition within the closed vessel. For example, the stationary piezoelectric material can be shaped as one or more rods extending from one end to the opposite end of the vessel. The impact material will be sloshed by the liquid to collide with the piezoelectric rod(s) which will augment the frequency of collisions and resulting voltages and currents. The rods will be connected to conductive loads that will transport the voltages and currents out of the closed vessels and into circuits or storage of electricity in capacitors or batteries as illustrated in FIG. 4.

The invention has been illustrated by the drawings and specification. Many variations will be evident to those skilled in the art. Therefore, it should be understood that all such variations are intended to be covered by the following claims and all equivalents thereof.

The following is claimed:

1. An electrical generator comprising:
(a) a closed vessel, containing a conductive wire, piezoelectric powder, impact material and a liquid; and
(b) said wire extending through to and extending beyond the vessel to create a circuit, whereby collisions of the impact material and piezoelectric powder create voltage and current pulses.

2. The generator of claim 1, wherein said piezoelectric powder is used in nanometer sizes.

3. The generator of claim 2, wherein said nanometer sizes comprise 300 to 500 nanometers.

4. The generator of claim 1, wherein said liquid is electrically inert.

5. The generator of claim 1, wherein said liquid is sufficiently viscous to maintain the piezoelectric powder and impact material in an intimate mixture.

6. The generator of claim 1, wherein said closed vessel has a rectangular shape and cross section.

7. The generator of claim 4 wherein the wire is centered in the vessel.

8. The generator of claim 1 wherein the liquid is partially filled in the vessel to enable the liquid to freely move when the vessel is moved.

9. The generator of claim 8 wherein the vessel is combined with a device that requires electric charging or recharging.

10. The generator of claim 9 wherein the device is portable.
